(19) United States
(12) Patent Application Publication
(10) Pub. No.: US 2018/0005678 A1
(43) Pub. Date: Jan. 4, 2018

(54) MEMORY DEVICE AND METHOD FOR OPERATING THEREOF

(71) Applicant: AGENCY FOR SCIENCE TECHNOLOGY AND RESEARCH, Singapore (SG)

(72) Inventors: Huey Chian FOONG, Singapore (SG); Fei LI, Singapore (SG)

(21) Appl. No.: 15/543,976

(22) PCT Filed: Dec. 31, 2015
(86) PCT No.: PCT/SG2015/050520

§ 371 Date: Jul. 14, 2017

(30) Foreign Application Priority Data
Jan. 15, 2015 (SG) 10201500289W

(51) Int. Cl. G11C 11/16; H01L 27/22

(52) U.S. Cl. CPC G11C 11/1673; H01L 27/228; G11C 11/1693; G11C 11/161; G11C 11/1655; G11C 11/1675

(57) ABSTRACT

According to various embodiments, there is provided a memory device including at least one sense amplifier having a first side and a second side, wherein the second side opposes the first side; a first array including a plurality of memory cells arranged at the first side; a second array including a plurality of memory cells arranged at the second side; a first row including a plurality of mid-point reference units arranged at the first side; and a second row including a plurality of mid-point reference units arranged at the second side, wherein each mid-point reference unit of the first row is configured to generate a first reference voltage, and wherein each mid-point reference unit of the second row is configured to generate a second reference voltage; wherein the sense amplifier is configured to determine a resistance state of a memory cell of the first array based on the second reference voltage; wherein the sense amplifier is configured to determine a resistance state of a memory cell of the second array based on the first reference voltage.

### CROSS-REFERENCE TO RELATED APPLICATIONS

This application claims the benefit of Singapore Patent Application number 10201500289W filed 15 Jan. 2015, the entire contents of which are incorporated herein by reference for all purposes.

### TECHNICAL FIELD

The present invention relates to memory devices and methods for operating thereof.

### BACKGROUND

In a conventional spin-transfer torque magnetoresistive random access memory (STTMRAM), a large write current may be required to programme the memory cells. As a result of the large current, the power consumption of the STTMRAM may be high. The large write current may necessitate the use of considerably large transistors, in order to reduce the undesired voltage drop across the resistance of the transistor when the transistor is turned on. The use of large transistors also leads to large integrated circuit area size of the memory and reduces the memory density.

As such, a new memory device and a method for operating thereof are required to overcome the disadvantages of existing memory devices such as the STTMRAM.

### SUMMARY

According to various embodiments, there may be provided a memory device including a sense amplifier having a first side and a second side, wherein the second side opposes the first side; a first array including a plurality of memory cells arranged at the first side; a second array including a plurality of memory cells arranged at the second side; a first row including a plurality of mid-point reference units arranged at the first side; and a second row including a plurality of mid-point reference units arranged at the second side, wherein each mid-point reference unit of the first row is configured to generate a first reference voltage, and wherein each mid-point reference unit of the second row is configured to generate a second reference voltage; wherein the sense amplifier is configured to determine a resistance state of a memory cell of the first array based on the second reference voltage; wherein the sense amplifier is configured to determine a resistance state of a memory cell of the second array based on the first reference voltage.

According to various embodiments, there may be provided a method for operating a memory device, the method including providing a sense amplifier, the sense amplifier having a first side and a second side, wherein the second side opposes the first side; providing a first array including a plurality of memory cells arranged at the first side; providing a second array including a plurality of memory cells arranged at the second side; providing a first row including a plurality of mid-point reference units arranged at the first side; providing a second row including a plurality of mid-point reference units arranged at the second side; and determining at least one of a resistance state of a memory cell of the second array based on a first reference voltage or a resistance state of a memory cell of the first array based on a second reference voltage; wherein the first reference voltage is generated by a mid-point reference unit of the first row, and wherein the second reference voltage is generated by a mid-point reference unit of the second row.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A shows a conceptual diagram of a memory device according to various embodiments.

FIG. 1B shows a conceptual diagram of a memory device according to various embodiments.

FIG. 2 shows a flow diagram of a method for operating a memory device, according to various embodiments.

FIG. 3 shows a schematic cross-sectional view of a memory cell according to various embodiments.

FIG. 4 shows the effect of a train of voltage pulses which may modulate the PMA of a free layer of a memory cell from its equilibrium value to zero, for pulses having duration of about 5 ns, according to various embodiments.

FIGS. 5A-5D show 3-dimensional representation of a coupled layer and a free layer magnetization vectors, according to various embodiments.

FIG. 6 shows the analytical estimation of the energy consumed to switch the magnetization of a free layer as a function of the duration of the voltage pulse and the resistance-area product of the insulating layer, according to various embodiments.

FIG. 7 shows the response of a Verlog-A model of a memory device to a train of pulses according to various embodiments.

FIG. 8 shows a top hierarchy memory architecture of a memory device according to various embodiments.

FIG. 9 shows a diagram 900 showing the architecture of a memory block of the memory device of FIG. 8.

FIG. 10 shows a diagram 1000 showing the architecture of a sub-block of the memory device of FIG. 9.

FIG. 11 shows a timing diagram of a memory write cycle according to various embodiments.

FIG. 12 shows the circuit blocks required for operating a memory cell according to various embodiments.

FIG. 13 shows a schematic diagram of a read/write controller according to various embodiments.

FIG. 14 shows a schematic diagram of a read/write controller according to various embodiments.

FIG. 15 shows a schematic diagram of an offset-cancellation two-stage sense amplifier according to various embodiments.

FIGS. 16A and 16B illustrate the operating principles of the offset-cancellation sense amplifier of FIG. 15.

FIG. 17 shows a schematic diagram of a midpoint resistance reference unit according to various embodiments.

FIG. 18 shows a timing diagram of the control signals of a mid-point reference unit according to various embodiments.

FIG. 19 shows a timing diagram showing the signal waveforms during operation of a TEFRAM in a burst-mode operation, according to various embodiments.

FIG. 20 shows a timing diagram 2000 showing the signal waveforms during the normal mode operation of a TEFRAM according to various embodiments.

FIG. 21 shows a table 2100 summarizing the features of a memory device according to various embodiments.

FIG. 22 shows a table 2200 summarizing a list of differences between a memory device according to various embodiments, as compared to a prior art STTRAM.

### DESCRIPTION

Embodiments described below in context of the devices are analogously valid for the respective methods, and vice versa. Furthermore, it will be understood that the embodiments described below may be combined, for example, a part of one embodiment may be combined with a part of another embodiment.

In the specification the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises”.

In order that the invention may be readily understood and put into practical effect, particular embodiments will now be described by way of examples and not limitations, and with reference to the figures.

Various embodiments are provided for devices, and various embodiments are provided for methods. It will be understood that basic properties of the devices also hold for the methods and vice versa. Therefore, for sake of brevity, duplicate description of such properties may be omitted.

It will be understood that any property described herein for a specific device may also hold for any device described herein. It will be understood that any property described herein for a specific method may also hold for any method described herein. Furthermore, it will be understood that for any device or method described herein, not necessarily all the components or steps described must be enclosed in the device or method, but only some (but not all) components or steps may be enclosed.

The term “coupled” (or “connected”) herein may be understood as electrically coupled or as mechanically coupled, for example attached or fixed, or just in contact without any fixation, and it will be understood that both direct coupling or indirect coupling (in other words: coupling without direct contact) may be provided.

In a conventional spin-transfer torque magnetoresistive random access memory (STTMRAM), a large write current may be required to programme the memory cells. As a result of the large current, the power consumption of the STTMRAM may be high. The large write current may necessitate the use of considerably large transistors, in order to reduce the undesired voltage drop across the resistance of the transistor when the transistor is turned on. The use of large transistors also leads to large integrated circuit area size of the memory and reduces the memory density. As such, a new memory device and a method for operating thereof are required to overcome the disadvantages of existing memory devices such as the STTMRAM.

In the context of various embodiments, “mid-point reference unit” may be but is not limited to being interchangeably referred to as a “mid-point reference circuit” or “midpoint reference unit”.

In the context of various embodiments, “top array” may be but is not limited to being interchangeably referred to as a “first array”.

In the context of various embodiments, “bottom array” may be but is not limited to being interchangeably referred to as a “second array”.

In the context of various embodiments, “top row” may be but is not limited to being interchangeably referred to as a “first row”.

In the context of various embodiments, “bottom row” may be but is not limited to being interchangeably referred to as a “second row”.

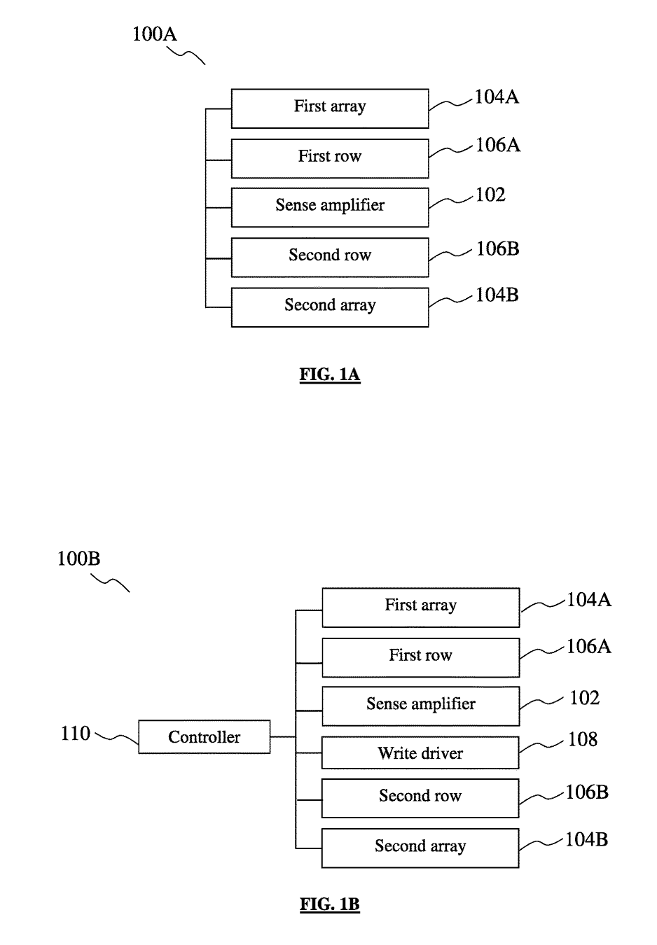

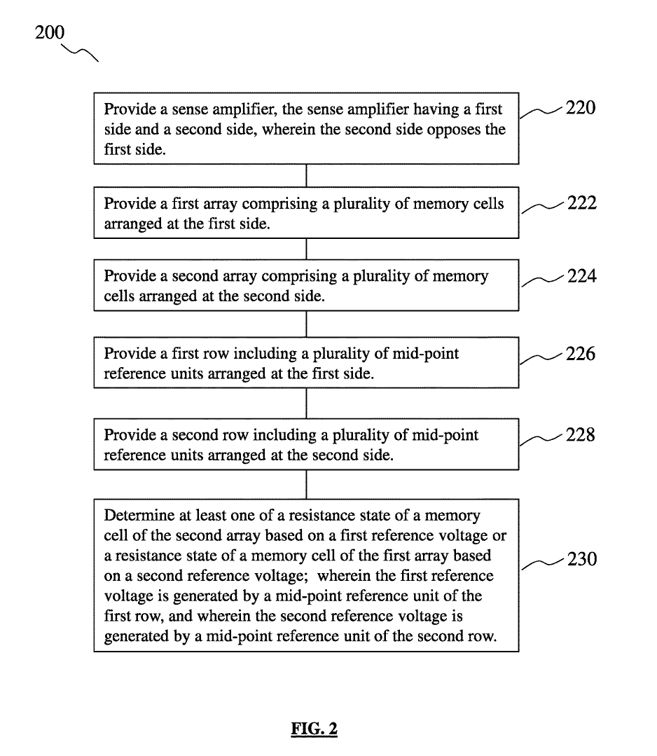

FIG. 1A shows a conceptual diagram of a memory device 100A, according to various embodiments. The memory device 100A may include a sense amplifier 102 having a first side and a second side, wherein the second side opposes the first side. The memory device 100A may further include a first array 104A, the first array 104A including a plurality of memory cells arranged at the first side of the sense amplifier 102. The memory device 100A may further include a second array 104B, the second array 104B including a plurality of memory cells arranged at the second side of the sense amplifier 102. The memory device 100A may further include a first row 106A including a plurality of mid-point reference units arranged at the first side of the sense amplifier 102. The memory device 100A may further include a second row 106B including a plurality of mid-point reference units arranged at the second side of the sense amplifier. Each mid-point reference unit of the first row 106A may be configured to generate a first reference voltage. Each mid-point reference unit of the second row 106B may be configured to generate a second reference voltage. The sense amplifier 102 may be configured to determine a resistance state of a memory cell of the first array 104A based on the second reference voltage. The sense amplifier 102 may also be configured to determine a resistance state of a memory cell of the second array 104B based on the first reference voltage. The memory device 100A may further include further sense amplifiers 102. A quantity of the sense amplifiers 102 may be at least substantially equal to a quantity of parallel data channels. In other words, the memory device 100A may include at least one sense amplifier. The memory device 100A may include one sense amplifier for each data channel. For example, the memory device 100A may include three sense amplifiers 102 to facilitate concurrent access to the memory cells via three data channels. The plurality of sense amplifiers 102 may be arranged in a row, such that the first side of one sense amplifier 102 is the same as the first side of another sense amplifier 102; and that the second side of one sense amplifier 102 is the same as the second side of another sense amplifier 102.

In other words, according to various embodiments, the memory device 100A may include a sense amplifier 102, a first array 104A, a second array 104B, a first row 106A and a second row 106B. The sense amplifier 102 may have a first side and a second side. The first side may be opposite to the second side. For example, the first side may be a top side of the sense amplifier 102 while the second side may be the bottom side of the sense amplifier 102. Each of the first array 104A and the second array 104B may include a plurality of memory cells. Each of the first array 104A and the second array 104B may include a plurality of columns, wherein each column may include a plurality of memory cells. In other words, each of the first array 104A and the second array 104B may include a plurality of memory cells arranged in a plurality of rows and a plurality of columns. The memory cells of the first array 104A may be at least substantially similar to the memory cells of the second array 104B. The first array 104A may be arranged at the first side while the second array 104B may be arranged at the second side. In other words, the first array 104A and the second array 104B are at two opposing sides of the sense amplifier 102. The sense amplifier 102 may be positioned between the first array 104A and the second array 104B. The sense amplifier 102 may be electrically coupled to each of the first array 104A and the second array 104B, for sensing the voltage across a memory cell that is to be read.

The memory device may include a plurality of mid-point reference units arranged in two rows, namely the first row 106A and the second row 106B. In other words, each of the first row 106A and the second row 106B may include a plurality of mid-point reference units. The first row 106A may be arranged adjacent to the second array 104B while the second row 106B may be arranged adjacent to the first array 104A. Each mid-point reference unit of the first row 106A may be configured to generate a first reference voltage while each mid-point reference unit of the second row 106B may be configured to generate a second reference voltage. Each mid-point reference unit may be configured to provide a mid-point resistance. The mid-point resistance may be at least substantially equal to an average of a high resistance state and a low resistance state. The mid-point reference units may be configured to generate the respective reference voltage based on the respective mid-point resistance. The mid-point reference units of the first row 106A may be at least substantially similar to the mid-point reference units of the second row 106B. The quantity of mid-point reference units in the first row 106A may be at least substantially equal to the quantity of columns in the second array 104B while the quantity of mid-point reference units in the second row 106B may be at least substantially equal to the quantity of columns in the first array 104A. The quantity of mid-point reference units in the first row 106A may be at least substantially equal to the quantity of mid-point reference units in the second row 106B.

The sense amplifier 102 may be configured to determine at least one of a resistance state of a memory cell of the first array 104A based on the second voltage or a resistance state of a memory cell of the second array 104B based on the first voltage. The first voltage used for determining the resistance state of the memory cell of the first array 104A may be generated by a mid-point reference unit in a same column as the memory cell of which its resistance state is to be determined. Similarly, the second voltage used for determining the resistance state of the memory cell of the second array 104B may be generated by a mid-point reference unit in a same column as the memory cell of which its resistance state is to be determined. For example, the sense amplifier 102 may determine the resistance state of a memory cell in the second column of the first array 104A, based on the mid-point reference unit in the second column of the second row 106B. Such an arrangement may facilitate ease of control signal routing. The determination of the resistance state of the memory cell of the first array 104A may be based on a comparison of the voltage of the memory cell with the second reference voltage while the determination of the resistance state of the memory cell of the second array 104B may be based on a comparison of the voltage of the memory cell with the first reference voltage. The sense amplifier 102 may include a first amplifier stage, a second amplifier stage and a plurality of capacitors connected between the first amplifier stage and the second amplifier stage. The plurality of capacitors may be configured, in a first mode of operation, to charge to a voltage corresponding to an offset voltage induced between inputs of the sense amplifier 102. The plurality of capacitors may be further configured, in a second mode of operation, to discharge the plurality of capacitors to counter the offset voltage induced between the inputs of the sense amplifier 102.

Each memory cell of each of the first array 104A and the second array 104B may include a reference magnetic layer structure having a fixed magnetization orientation; and a synthetic antiferromagnetic layer structure comprising a free magnetic layer structure and a coupling magnetic layer structure antiferromagnetically coupled to each other, each of the free magnetic layer structure and the coupling magnetic layer structure having a magnetization orientation that is variable, wherein the reference magnetic layer structure and the synthetic antiferromagnetic layer structure are arranged one over the other. Each mid-point reference unit of the first row 106A and the second row 106B may also include a plurality of memory cells. The memory cells in the mid-point reference units may be at least substantially similar to the memory cells in the first array 104A and the memory cells in the second array 104B.

FIG. 1B shows a conceptual diagram of a memory device 100B, according to various embodiments. The memory device 100B may be similar to the memory device 100A of FIG. 1A, in that it includes a sense amplifier 102, a first row 106A comprising a plurality of mid-point reference units, a second row 106B comprising a plurality of mid-point reference units, a first array 104A comprising a plurality of memory cells, and a second array 104B comprising a plurality of memory cells. The memory device 100B may further include a write driver 108 and a controller 110. The write driver 108 may be configured to toggle the resistance state of at least one of a memory cell of the first array 104A or a memory cell of the second array 104B. The write driver 108 may be configured to toggle the resistance state between a high resistance state and a low resistance state. For example, if an existing resistance state of the memory cell is high, the write driver 108 can toggle the resistance state to low, vice-versa. The write driver 108 may be configured to toggle the resistance state of any memory cell only after the resistance state of the memory cell is determined by the sense amplifier. In other words, the sense amplifier 102 may be configured to determine the resistance state of at least one of the memory cell of the first array or the memory cell of the second array before the write driver 108 toggles the resistance state of the memory cell of the first array or the memory cell of the second array. The memory device 100A may further include further sense amplifiers 102. A quantity of the sense amplifiers 102 may be at least substantially equal to a quantity of parallel data channels. The plurality of sense amplifiers 102 may be arranged in a row, such that the first side of one sense amplifier 102 is the same as the first side of another sense amplifier 102; and that the second side of one sense amplifier 102 is the same as the second side of another sense amplifier 102. The memory device 100A may further include further write drivers 108. A quantity of the write drivers 108 may be at least substantially equal to a quantity of parallel data channels. In other words, the memory device 100A may include at least one write driver. The memory device 100A may include one write driver 108 for each data channel. For example, the memory device 100A may include three write drivers 108 to facilitate concurrent writing to the memory cells via three data channels. The plurality of write drivers 108 may be arranged in a row.

Each of the mid-point reference units may include a plurality of memory cells. The write driver 108 may be further configured to toggle the resistance state of the memory cells of each mid-point reference unit. According to various embodiments, each of the mid-point reference units may include four memory cells. When a mid-point reference unit is in a programming mode, the four memory cells may be connected in parallel. The write driver 108 may be configured to program two memory cells of the four memory cells to a high resistance state and may be further configured to program the other two memory cells to a low resistance state. When the mid-point reference unit is in a read mode, the four memory cells may be arranged in two branches connected in parallel, wherein each branch of the two branches may include a memory cell in the high resistance state connected in series to a memory cell in the low resistance state. With this circuit arrangement, the mid-point reference unit may provide a mid-point resistance through the four memory cells.

The controller 110 may be electrically coupled to the sense amplifier 102. The controller 110 may include a plurality of D flip-flops. The controller 110 may be configured to generate internal control signals. The internal control signals may be generated based on the input data and an output signal of the sense amplifier 102. The controller may be further configured to compare an input data to the resistance state of a memory cell, the input data being data that is to be written to the memory cell. The controller may be further configured to generate the internal control signals to toggle the resistance state of the at least one of the memory cell of the first array or the memory cell of the second array if the resistance state of the at least one of the memory cell of the first array or the memory cell of the second array is not at least substantially matched to the input data. For example, if the input data is “1” and the resistance state of the memory cell to be written to is low, the controller may generate an internal control signal for controlling the write driver 108 to toggle the resistance state of the memory cell to high resistance state. On the other hand, if the resistance state of the memory cell to be written to, is already high, the controller may generate an internal control signal to control the write driver 108 not to toggle the resistance state of the memory cell or alternatively the controller may not generate any internal control signal for operating the write driver 108.

The internal control signals may be used to at least one of address the selected memory cell, control the write driver or control the sense amplifier 102. The controller 110 may be further configured to sample rising edges of a clock signal and falling edges of the clock signal, and may be further configured to align the internal control signals to the rising edges of the clock signal and the falling edges of the clock signal. The controller 110 may include a plurality of digital delay elements configured to align edges of the internal control signals to the rising edges of the clock signal and the falling edges of the clock signal.

FIG. 2 shows a flow diagram 200 of a method for operating a memory device, according to various embodiments. The method may include processes 220, 222, 224, 226, 228 and 230. In 220, a sense amplifier may be provided. The sense amplifier may have a first side and second side, the second side opposing the first side. In 222, a first array including a plurality of memory cells may be provided. The first array may be arranged at the first side. In 224, a second array including a plurality of memory cells may be provided. The second array may be arranged at the second side. In 226, a first row including a plurality of mid-point reference units may be provided. The first row may be arranged at the first side. In 228, a second row including a plurality of mid-point reference units may be provided. The second row may be arranged at the second side. In 230, at least one of a resistance state of a memory cell of the second array may be determined based on a first reference voltage or a resistance state of a memory cell of the first array may be determined based on a second reference voltage. The first reference voltage may be generated by a mid-point reference unit of the first row. The second reference voltage may be generated by a mid-point reference unit of the second row. The method may further include receiving an input data. The method may further include comparing the input data to the determined resistance state. The method may further include toggling the determined resistance state if the determined resistance state is not at least substantially matched to the input data.

A memory device according to various embodiments may be a nonvolatile memory system. The memory device may be implemented using TEF memory and circuits. In other words, the memory cells of the memory device may be TEF random access memory (TEFRAM) cells.

A memory device according to various embodiments may be designed based on memory segmentation, which may include hierarchies of memory arrays to reduce bitline and wordline loading and also to improve access speed. The memory device may include a plurality of memory sub-blocks. At the lowest memory hierarchy, the memory sub-block may adopt open bitline architecture to achieve high memory density and also to maintain equal loading seen by the inputs of the sense amplifiers. The sub-block may include a plurality of memory cells. The memory cells may be partitioned or arranged into a first array and a second array. The first array may also be referred herein as the top array, while the second array may also be referred herein as the bottom array. The sub-block may further include at least one row of mid-point reference units; a plurality of sense amplifiers wherein a quantity of the sense amplifiers is at least substantially equal to a quantity of data channels; a write driver; a plurality of row decoders and a plurality of column decoders, and a sub-block controller. The sub-block may include a first row of mid-point reference unit and a row of second mid-point reference unit. The first row of mid-point reference unit may also be referred herein as the top row of mid-point reference unit, while the second row of mid-point reference unit may also be referred herein as the bottom row of mid-point reference unit. The top row of mid-point reference unit and the bottom row of mid-point unit may be positioned between the top array and the bottom array. The write driver and the sense amplifier may also be located between the top array and the bottom array, for ease of access to the memory cells and to the mid-point reference units. The write driver and the sense amplifier may also be positioned between the top row of mid-point reference unit and the bottom row of mid-point unit. When a memory cell from the top array is selected, a corresponding mid-point reference unit from the bottom row of mid-point reference units and of the same column as the selected memory cell may be used for comparison and vice versa.

A mid-point reference unit according to various embodiments may include four memory cells. Two memory cells may be connected in series in a first branch and another two memory cells may be connected in series in a second branch. The first branch may be connected in parallel to the second branch. In each of the first branch and the second branch, the two memory cells may be a high resistance memory cell and a low resistance memory cell. In other words, the four memory cells may be connected in the way of two parallel branches of a high resistance memory cell in series with a low resistance memory cell to achieve a mid-point resistance. The mid-point resistance may be denoted as R_{MP}=(R_{H}+R_{L})//(R_{H}+R_{L})=(R_{H}+R_{L})/2.

A memory device according to various embodiments may include a two-stage off-set cancellation sense amplifier. The difference in parasitic capacitance and coupling effect between a mid-point reference unit and a memory cell may result in a mismatch at the inputs of a conventional sense amplifier, which may result in an offset error. A two-stage offset-cancellation sense amplifier may circumvent the offset error, by storing the offset voltage during precharge phase and then cancelling out the offset error during read phase to reduce the read error. The offset-cancellation sense amplifier may be reused for reading the memory cells and therefore, no additional sense amplifier may be required.

A memory device according to various embodiments may employ a read-before-write scheme. A TEFRAM may exhibit toggling behavior during write, in other words, the same write pulse may switch the resistance state of a memory cell to either high resistance or low resistance based on its previous state. For example, if the previous state is high resistance, the write pulse may switch the resistance state of the memory cell to low resistance and the same write pulse may switch the resistance state of the memory cell to high resistance if the previous state of the memory cell is low resistance. In view of the toggling behavior of the TEFRAM, a read-before-write scheme may be employed during memory write. The read-before-write scheme may be controlled by a memory read/write controller. The controller may generate a plurality of internal control signals, including precharge, discharge, sense amplifier enable and write enable signals. The internal control signals may be aligned to edges of a clock signal. The controller may determine the need to generate the internal write enable pulse based on an input data and the data sensed from the memory cell. The input data may be the data that is to be written to the memory cell. The data may be sensed from the memory cell by determining the resistance state of the memory cell.

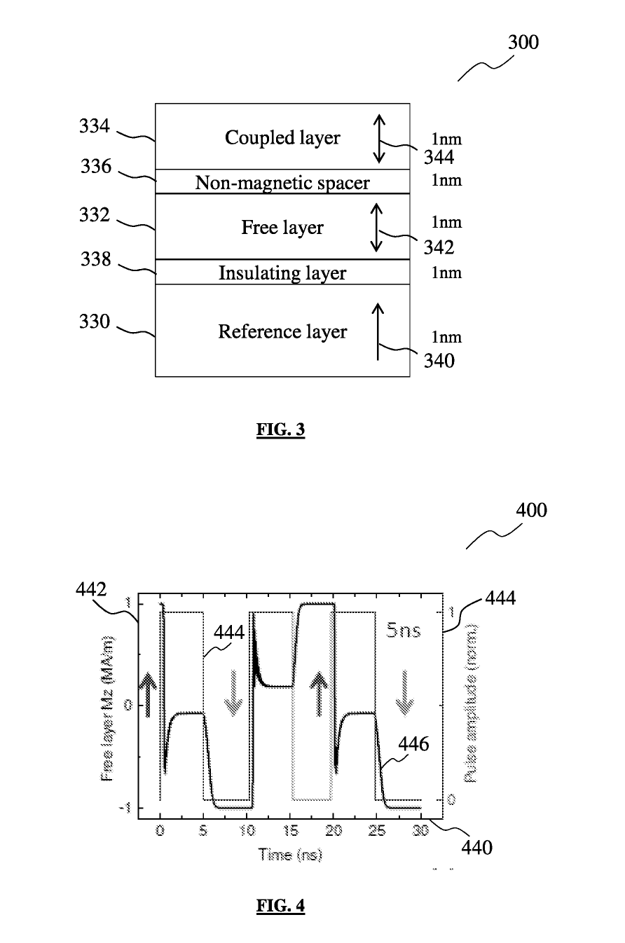

FIG. 3 shows a schematic cross-sectional view of a memory cell 300 according to various embodiments. The memory cell may include a reference layer 330, a free layer 332, a coupled layer 334, a non-magnetic spacer 336 and an insulating layer 338. The reference layer 330 may be a magnetic layer structure and may also be referred herein as a ferromagnetic reference layer. The free layer 332 may also be referred herein as a free magnetic layer structure. The coupled layer 334 may also be referred herein as a coupling magnetic layer structure or a ferromagnetic coupled layer. The insulating layer 338 may be a non-magnetic insulating layer, for example, a magnesium oxide (MgO) layer. The coupled layer 334 may be magnetically coupled to the free layer 332, for example, the free layer 332 and the coupled layer structure 334 may be antiferromagnetically coupled to each other, for example, through the non-magnetic spacer 336. The reference layer 330 may be a single reference layer. The memory cell 300 may have perpendicular magnetic anisotropy (PMA). This may mean, for example, that all ferromagnetic layers (e.g., reference layer 330, free layer 332 and coupled layer) may possess perpendicular magnetic anisotropy (PMA). Magnetizations or magnetization orientations of the reference layer 330, the free layer 332 and the coupled layer 334 may be out of the layers' planes, for example corresponding to planes of the layers' respective major surfaces. The reference layer 330 may have a fixed magnetization orientation (as represented by the single-headed arrow 340 representing a typical orientation of the magnetization of the reference layer 330), for example, fixed in an upwardly direction. Each of the free layer 332 and the coupled layer 334 may have a variable magnetization orientation (as represented by the double-headed arrows 342, 344) that may point in an upwardly direction or a downwardly direction. The double-headed arrows 342, 347 represent the orientations of the magnetizations of each of the free layer 332 and the coupled layer 334 and indicate that both of these layers' magnetization orientations may be changed during a write operation.

The reference layer 330 may possess a strong perpendicular uniaxial magnetic anisotropy which may prevent it from being affected by external and internal magnetic perturbations. The perpendicular magnetic anisotropy of the free layer 332 may have its source at least partially from the interface with the insulating layer 338 (also known as interfacial magnetic anisotropy) so that its magnetic anisotropy may be tuned by an electric field (E-field). The material for the free layer 332 may have high spin polarization to have high tunnel magnetoresistance (TMR). The free layer 332, the non-magnetic spacer 336 and the coupled layer 334 may constitute or define a synthetic anti-ferromagnet (SAF) structure. Due to the antiferromagnetic coupling, the moments or magnetization orientations 342, 344 of the free layer 332 and the coupled layer 334 may point in opposite direction in the absence of an applied field. The non-magnetic spacer 336 may include at least one of the elements: ruthenium (Ru), rhodium (Rh), chromium (Cr), vanadium (V), molybdenum (Mo), or combinations and alloys of these such as ruthenium-tantalum (Ru—Ta). The thickness range of the non-magnetic spacer 336 may be at least substantially in the range of 3-20 angstroms (or 0.3-2 nm), depending upon the coupling peak of the material used.

In various embodiments, it may be desirable to have a slight magnetic imbalanced SAF structure, which may cause the magnetization to fall into a preferred state upon application of an electric field. An imbalance may be accomplished by having Mₛ₁×t₁>Mₛ₂×t₂, where Mₛ₁ and t₁ are the saturation magnetization and thickness, respectively, of the free layer 332, and Mₛ₂ and t₂ are the saturation magnetization and thickness, respectively, of the coupled layer 334.

In various embodiments, the damping factor of the free layer 332 may not play a critical role in the overall energy consumption to switch a memory cell, as opposed to conventional devices which use the spin transfer torque (STT) effect to switch the memory cell.

In various embodiments, no in-plane magnetic field is required for switching the magnetization orientation 342 of the free layer 332.

FIG. 4 shows a graph 400 showing the effect of a train of voltage pulses which may modulate the PMA of the free layer 332 from its equilibrium value to zero, for pulses having a duration of about 5 ns. The repetition rate of the pulses has been set to the minimum time required for the system (or magnetic tunnel junction) to relax to equilibrium. The graph 400 includes a horizontal axis 440 indicating time in nanoseconds; a first vertical axis 442 indicating projection of the magnetization of the free layer 332 along the out of plane axis (z) (or growth axis), Mz; and a second vertical axis 444 indicating normalized pulse amplitude. The graph 400 further includes a first plot 444 and a second plot 446. The first plot 444 represents the pulses, and are associated with the second axis 444 representing the normalized amplitude of a voltage pulse applied (where a value of 0 is equivalent to the amplitude of the magnetic anisotropy of the free layer 332 being equal to its equilibrium value). The second plot 446 represents the projection of the magnetization of the free layer 332 along the out of plane axis (z) (or growth axis) and are associated with the first axis 442. The respective arrows shown in the graph 400 represent the direction of switching of the free layer 332 in response to a respective voltage pulse. It may be observed that the magnetization of the free layer 332 may switch from the +z direction to the −z direction and vice versa every time a respective voltage pulse is applied. The magnetization orientation of the free layer 332 may switch from one direction to the other every time a pulse occurs, regardless of the presence of a strong stray field due to the presence of a reference layer 330 without SAF. Consistent bipolar switching of the magnetization or magnetization orientation of the free layer 332 may be achieved with a unipolar voltage pulse.

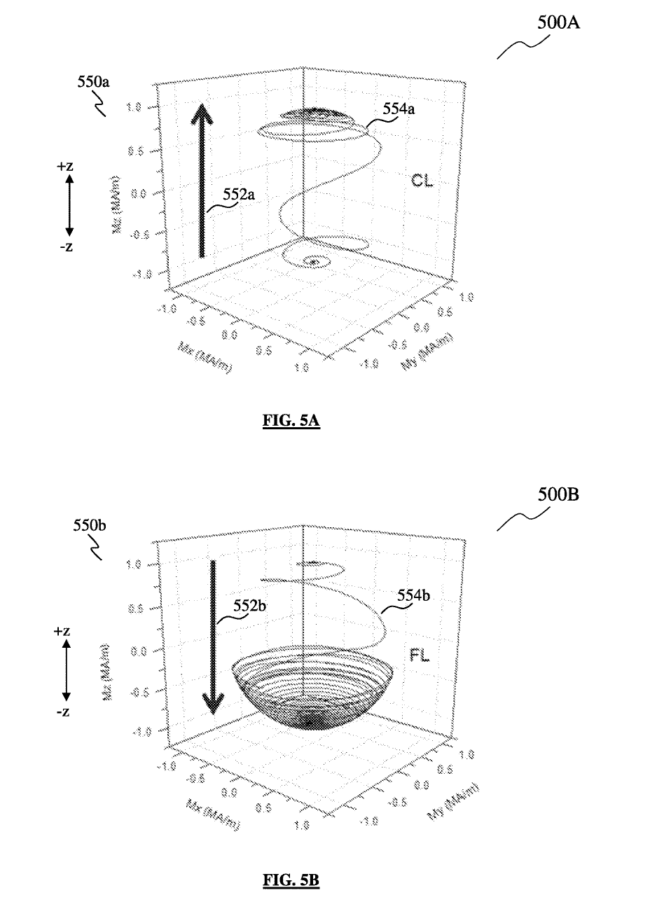

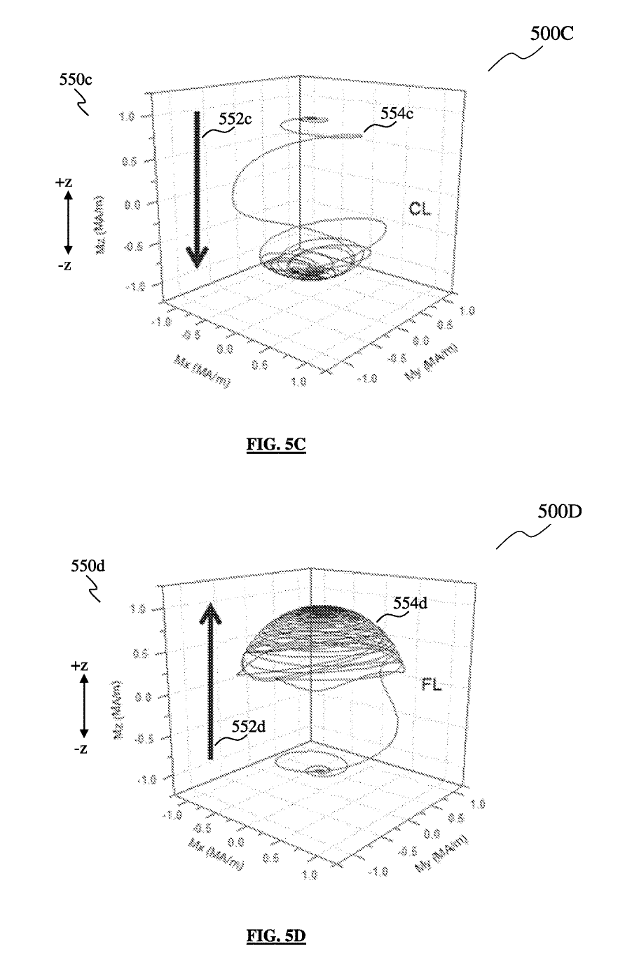

FIGS. 5A-5D show micromagnetics simulation results using Object Oriented Micro Magnetics Framework (OOMMF), illustrating 3-dimensional representation of the coupled layer (e.g., 334) and the free layer (e.g., 332) magnetization vectors for all times simulated. In order to understand the nature of the switching in various embodiments, the magnetization vectors of both the coupling layer (CL) and the free layer (FL), for a 1 ns voltage pulse may be plotted for the respective processes corresponding to the switching of the magnetization orientation of the FL from up to down (see FIGS. 5A and 5B) and the switching of the magnetization orientation of the FL from down to up (see FIGS. 5C and 5D). FIGS. 5A, 5B, 5C and 5D include plots 550a, 550b, 550c and 550d respectively. The respective arrows 552a, 552c in each respective plot 550a, 550c represent the direction followed by the magnetization of the CL during switching. The respective arrows 552b, 552d in each respective plot 550b, 550d represent the direction followed by the magnetization of the FL during switching.

FIGS. 5A and 5B show, for a first 1 ns voltage pulse, the respective plots 550a, 550b where the magnetization of the CL switches from the −z direction to the +z direction (represented by the arrow 552a and the magnetization vector 554a), and where the magnetization of FL switches from the +z direction to the −z direction (represented by the arrow 552b and the magnetization vector 554b), as both the CL and the FL are coupled antiferromagnetically to each other.

FIGS. 5C and 5D show, for a second 1 ns voltage pulse, the respective plots 550c, 550d where the magnetizations of the CL and the FL switch back to their original relative orientations. In other words, FIG. 5C shows the results where the magnetization orientation of the CL switches from the +z direction to the −z direction (represented by the arrow 552c and the magnetization vector 554c), while FIG. 5D shows the results where the magnetization orientation of the FL switches from the −z direction to the +z direction (represented by the arrow 552d and the magnetization vector 554d), as both the CL and the FL are coupled antiferromagnetically to each other.

Referring to FIGS. 5A to 5D, the switching mechanism of the magnetizations of both the CL and the FL is precession, as evidenced by the shape of the time dependent magnetization vectors 554a, 554b, 554c, 554d.

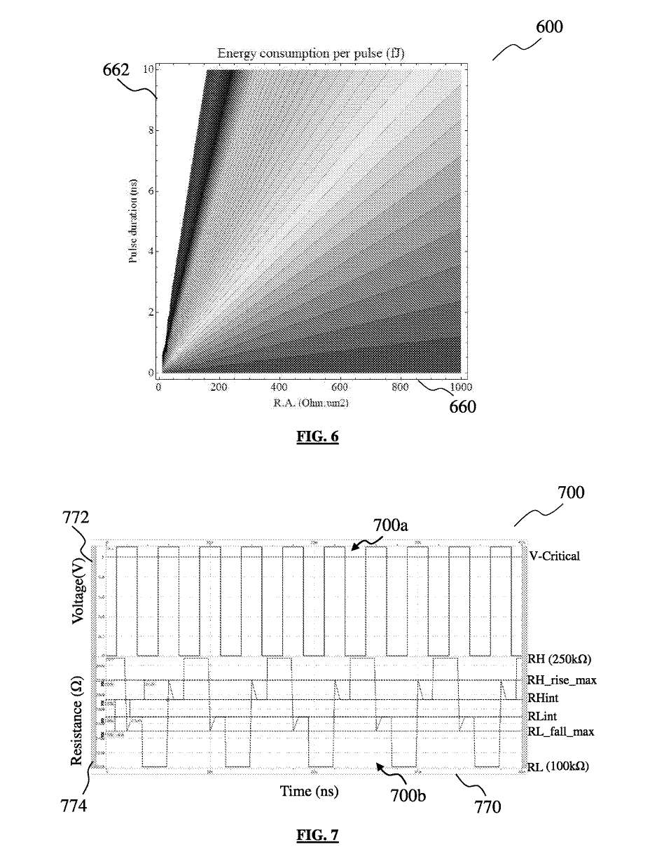

FIG. 6 shows a graph 600 showing the analytical estimation of the energy consumed to switch the magnetization of the FL as a function of the duration of the voltage pulse and the resistance-area (RA) product of the insulating layer, according to various embodiments. The graph 600 may be plotted using the same information or data as used for the simulation as described above, the energy consumption that may be required to switch one bit of information. As may be observed, any pulse duration above 500 ps (i.e., 0.5 ns ) results in deterministic switching of the magnetization of the FL. Considering an insulating layer with a resistance-area product of about 500 Ω·μm², bit writing for approximately 1.5 fJ may be achieved for a 40×40 nm² MTJ (magnetic tunnel junction), which is more than 50-fold reduction as compared to prior art STT-MRAM results.

FIG. 7 shows a Verlog-A model 700 of a memory device according to various embodiments. The Verlog-A model 700 includes a first graph 700a showing a voltage pulse having a period of about 5 ns, the voltage pulse used for writing to a memory cell according to various embodiments; and a second graph 700b showing the resistance level of the memory cell, written to by the voltage pulse of the first graph 700a. The first graph 700a includes a horizontal axis 770 indicating time in nanoseconds and a vertical axis 772 indicating voltage in volts; the second graph 700b includes a horizontal axis 770 and a vertical axis 774 indicating resistance in ohms.

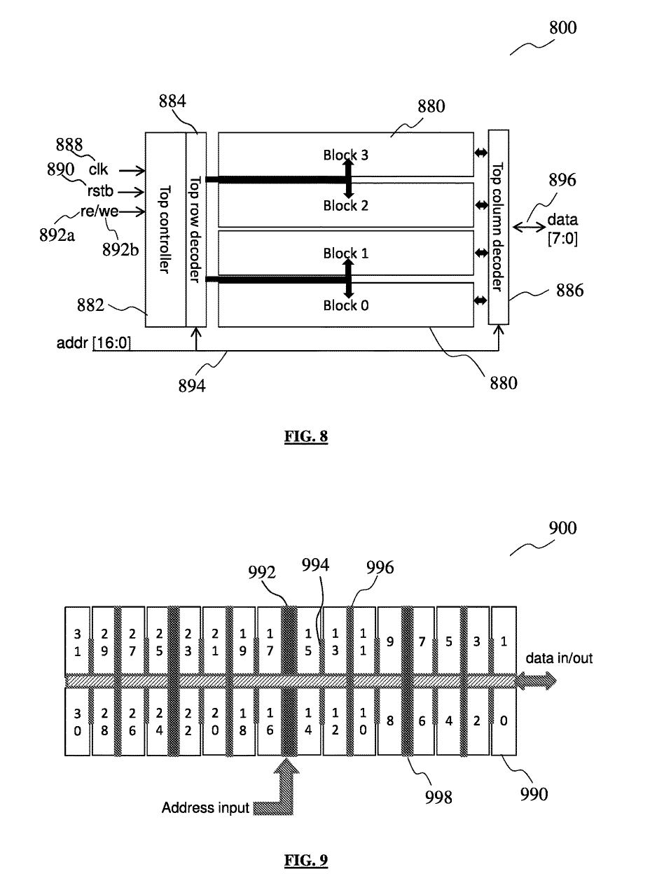

FIG. 8 shows a top hierarchy memory architecture of a memory device 800 according to various embodiments. The memory device 800 may be a synchronous toggle electric field random access memory (TEFRAM) device. The memory device 800 may include a plurality of memory blocks 880, a top controller 882, a row decoder 884 and a column decoder 886. While the memory device 800 as shown in FIG. 8 includes four memory blocks 880, the memory device 800 according to other embodiments may have other quantities of memory blocks 880. The top controller 882 may be configured to interface with an external device such as a computer central processing unit, through a plurality of interfacing signals. The plurality of interfacing signals may include a clock signal 888 denoted by “clk”; a reset signal 890 denoted by “rstb”; a read enable signal 892a denoted by “re”; a write enable signal 892b denoted by “we”; an address bus 894 denoted by “addr”; and a data bus 896 denoted by “data”.

FIG. 9 shows a diagram 900 showing the architecture of a memory block 880 of the memory device 800 of FIG. 8. The diagram depicts the memory segmentation of each TEFRAM block of FIG. 8. Each TEFRAM block may include a number of sub-blocks and a number of decoders from different hierarchies. The memory block may include a plurality of memory sub-blocks 990. In FIG. 9, the memory block is depicted as include 32 memory sub-blocks 990 but other embodiments may have a different quantity of sub-blocks 990. Each sub-block 990 may have a smaller number of TEFRAM cells compared to a memory block. In between the sub-blocks 990, there may be different hierarchies of decoders to address every memory cell. The decoders may include global row decoders 992, precoder 994, local decoder 996, and subglobal row decoder 998.

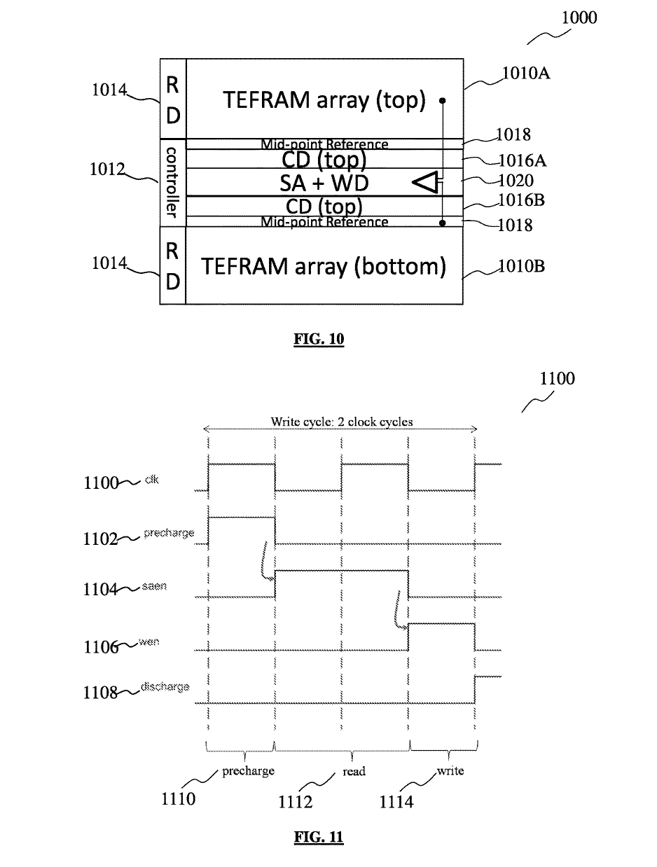

FIG. 10 shows a diagram 1000 showing the architecture of the sub-block 990 of FIG. 9. The sub-block 990 may include top and bottom partitions of TEFRAM memory array, namely a top memory array 1010A and a bottom memory array 1010B. Each of the top memory array 1010A and the bottom memory array 1010B may include a plurality of rows and a plurality of columns. The sub-block 990 may also include a controller 1012, two row decoders (RD) 1014, a top column decoder (CD) 1016A, a bottom column decoder 1016B and two rows of mid-point reference units 1018. The sub-block 990 may further include a plurality of sense amplifiers (SA) and a plurality of write drivers (WD), housed in the same layer 1020 of the sub-block 990. A quantity of the sense amplifiers in the plurality of sense amplifiers may be at least substantially equal to a quantity of parallel data channels of the sub-block 990. In other words, the sub-block 990 may include one sense amplifier for each data channel. A quantity of the write drivers in the plurality of write drivers may be at least substantially equal to a quantity of parallel data channels of the sub-block 990. In other words, the sub-block 990 may include one write driver for each data channel. The sub-block 990 may employ an open bitline architecture with the sense amplifiers, write drivers, the top column decoder 1016A and the bottom column decoder 1016B located between the top array 1010A and the bottom array 1010B. One row of the two rows of mid-point reference units 1018 may be located between the top column decoder 1016A and the top memory array 1010A. The other row of the two rows of mid-point reference units 1018 may be located between the bottom column decoder 1016B and the bottom memory array 1010B. When a memory cell from the top memory array 1010A is selected, a corresponding mid-point reference unit 1018 from the bottom memory array 1010B of the same column may be selected for comparison and vice versa. This is to maintain nearly equal loading seen by the inputs of the sense amplifiers.

FIG. 11 shows a timing diagram 1100 of a memory write cycle according to various embodiments. The timing diagram 1100 depicts the internal control signals for a TEFRAM cell. The internal control signals includes a clock signal (CLK) 1100, a precharge signal (precharge) 1102, a sense amplifier enable signal (saen) 1104, a write enable signal (wen) 1106 and a discharge signal (discharge) 1108. Due to the toggling behavior of TEFRAM, a write pulse may be able to switch the memory cell to either high resistance or low resistance based on the previous state of the memory cell. Therefore, a read-before-write scheme may be required for the write operation of TEFRAM to avoid write error. In other words, the memory cell may be read before the memory cell is written to. The sense amplifiers employed in the write scheme may be common for both write and read operations and therefore, additional sensing circuits may not be required. The timing diagram 1100 shows the internal control signals CLK 1100, precharge 1102, saen 1104, en 1106 and discharge 1108 for a single write cycle. The write cycle may have a duration of two clock cycles or in other words a duration of two periods.

The write cycle may be divided into three phases, namely a precharge phase 1110, a read phase 1112 and a write phase 1114. The first half of the first clock period may be the precharge phase 1110. During the precharge phase 1110, a precharge pulse may be generated as part of the precharge signal 1102 and the selected bitline may be pulled to a precharge voltage. The precharge voltage may be about 0.5V. The next one clock period may be the read phase 1112. During the read phase 1112, the sense amplifier enable signal 1104 may be high so as to activate the sense amplifier. A read current may be steered towards the selected memory cell, and a mirrored read current of the same value may be steered towards the midpoint reference unit 1018. The direction of the read current may be of the same polarity or reversed polarity as compared to the write current. The read current may be driven to the memory cell from the reversed direction as compared to the write current to prevent read disturbance. The sense amplifier may then compare the voltage at the inputs to the voltage generated by the midpoint reference unit 1018 across the mid-point resistance generated by the mid-point reference unit 1018, to determine the resistance state of the selected memory cell. During the write phase 1114, the controller 1012 may decide whether a write enable pulse of half-clock period should be switched high based on read output to toggle the resistance state to match with the input data.

FIG. 12 shows a diagram 1200 showing the circuit blocks required for operating a memory cell, according to various embodiments. The circuit blocks may perform functions including read and write, as well as provide the corresponding control signals. In other words, the circuit blocks may control the write and read of a memory cell 1220 and condition the bitlines, such as bitline precharge and discharge blocks, and the corresponding control signals. The circuit blocks may include a read/write controller 1012, a bitline precharge circuit 1222, a bitline discharge circuit 1224, a write driver 1226, a sense amplifier 1228 and a midpoint reference unit 1018. The read/write (R/W) controller 1012 may be configured to generate the internal control signals, e.g. precharge (prech) 1112, discharge (disch) 1118, sense amplifier enable (saen) 1114 and write enable (wen) signals 1116, which may be aligned to the clock edges. The R/W controller 1012 may also decide on the need to generate the internal write enable (wen) 1116 pulse based on the input data (din) 1230 and the sensed data (dsa) 1232 from the memory cell 1220. A clamping transistor 1234 may be connected between the bitline and the sense amplifier 1228 or write driver 1226 to prevent read disturbance to the memory cells 1220 by connecting its gate to a clamp voltage (Vclamp) 1236 during read and to prevent overdriving the memory cell to avoid breakdown of the memory during write. During write, the gate of the clamping transistor is connected to another voltage, e.g. a boosted voltage 1238, to provide the voltage required to toggle the memory state. The boosted voltage 1238 may compensate the gate-to-source voltage or Vgs drop of the clamping transistor 1234 during write operation.

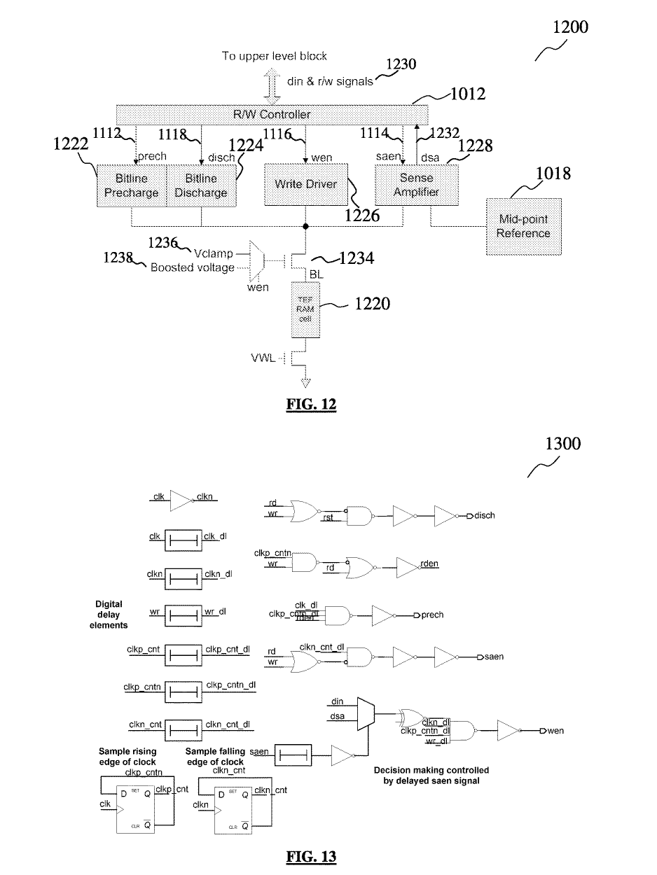

FIG. 13 shows a schematic diagram 1300 of the read/write controller 1012 of FIG. 12. The read/write controller 1012 may be locally embedded in the memory sub-block 880 in the vicinity of the write drivers 1226 and sense amplifiers 1228. The read/write controller 1012 may include two D flip-flops to sample the rising and falling edges of the clock signal to align the control signals to the clock edges. D flip-flop is a circuit that has two stable states and may be used to store state information. The read/write controller 1012 may further include several digital delay elements to align the edges of the internal control signals and to remove undesirable glitches. The read/write controller 1012 may also include a decision making circuit based on the input data, din 1230, and the sense amplifier output signal, dsa 1232. The decision making circuit may be controlled by the delayed sense amplifier enable (saen) signal 1114 to achieve correct latching of the sensed signal.

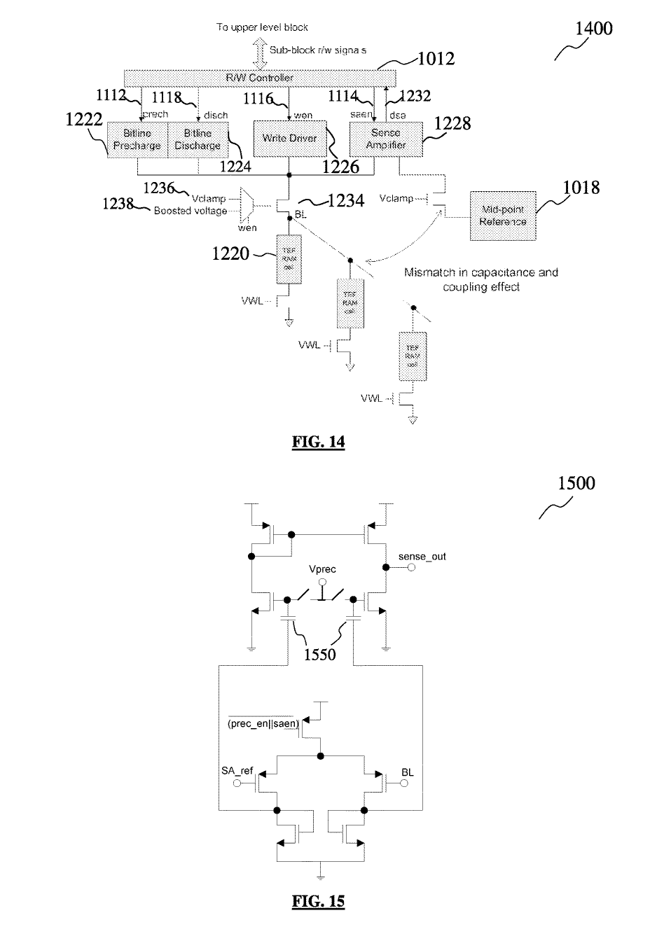

FIG. 14 shows a schematic diagram 1400 of a read/write controller 1012 according to various embodiments. The schematic diagram 1400 shows the mismatch of the bitline and reference at the inputs of the sense amplifier 1228. The schematic diagram 1400 depicts the difference in parasitic capacitance and coupling between the bitline and the midpoint reference unit 1018. One input of the sense amplifier 1228 may be connected to the selected memory cell 1220 and the other input may be connected to the selected mid-point reference unit 1018. The mismatch may result due to the difference in parasitic capacitance of the bitline and the reference line and the signal coupling effect of the memory cell 1220 and that of the midpoint reference unit 1018. The mismatch may generate an offset voltage for the sense amplifier 1228, which may result in a read error.

FIG. 15 shows a schematic diagram of an offset-cancellation two-stage sense amplifier 1500 according to various embodiments. The sense amplifier 1500 may be the sense amplifier 1228 of FIGS. 12 and 14. The sense amplifier 1500 may include two amplifier stages with two capacitors 1550 connected in series between the first and second stages. One terminal of the capacitor 1550 may be connected to the output of the first stage while the other terminal is connected to the input of the second stage. The first stage may have a diode connected load and the second stage may have a current mirror load. It may also include switches to connect the input of second stage to the precharge voltage. The capacitors 1550 may be used to store the offset voltage during precharge phase and may be further used to cancel the offset voltage during read phase.

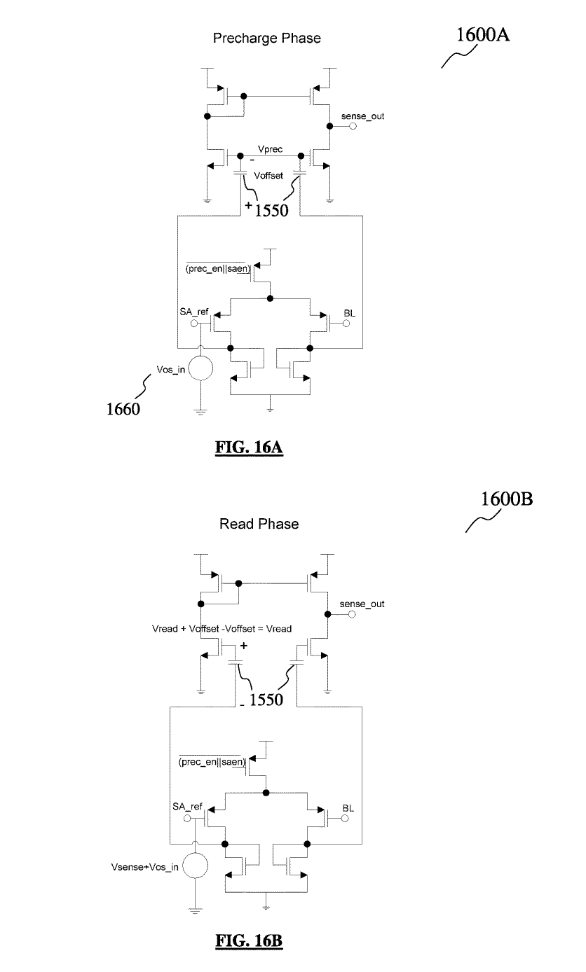

FIGS. 16A and 16B illustrate the operating principles of the offset-cancellation sense amplifier 1500 of FIG. 15. FIG. 16A shows a schematic diagram 1600A showing the circuit configurations of the sense amplifier 1500 during the precharge phase. During the precharge phase, the top terminals of the capacitors 1550 may be connected to the precharge voltage. As both SA_ref and BL are precharged to the same precharge voltage, the offset voltage (Vos_in 1660) from the input pair may be stored at the bottom terminals of the two capacitors 1550 as Voffset. Vos_in 1660 represents the offset voltage or the voltage difference in charging of the bitline and reference node, the offset voltage resulting due to parasitic mismatch.

FIG. 16B shows a schematic diagram 1600B showing the circuit configurations of the sense amplifier 1500 during the read phase. During the read phase, the voltage difference between the input pair may be Vsense+Vos_in, and the corresponding voltage difference at the gates of the NMOS pair in the second stage may be Vread+Voffset. The offset voltage may be cancelled out from the read voltage (Vread) at the capacitors 1550, which may lead to an accurate readout. The sense amplifier 1500 may be capable of cancelling the offset voltage due to the mismatch in the bitline and the reference line contributed by the devices preceding the sense amplifier 1500. The series configuration may be more effective than the parallel configuration as the capacitors 1550 may be coupled directly to the signal path.

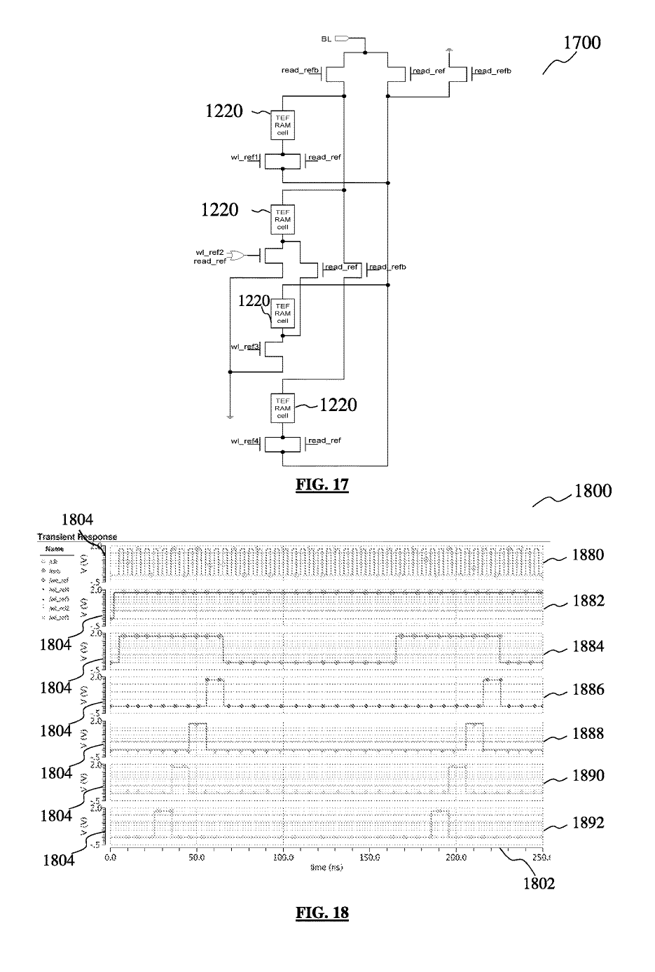

FIG. 17 shows a schematic diagram of a midpoint resistance reference unit 1700 according to various embodiments. The midpoint resistance reference unit 1700 may be the midpoint reference unit 1018 of FIG. 5. The midpoint resistance reference unit 1700 may include four TEFRAM cells 1220 and a number of pass transistors or control switches. During the read phase, the midpoint resistance may be formed by two parallel branches of a TEFRAM cell 1220 in a high-resistance state and a TEFRAM cell 1220 in a low-resistance state in series based on the following equation:

$$( {R}_{H} + {R}_{L} ) // ( {R}_{H} + {R}_{L} ) = \frac{{R}_{H} + {R}_{L}}{2}$$

The pass transistors may be sized large enough such that their respective on-resistances are negligible compared to the resistance of the memory cells 1220. The midpoint resistance reference circuit 1700 may be capable of tracking temperature changes by employing memory cells 1220. During read, read_ref is ‘1’, and read_refb is ‘0’. The mid-point reference unit may be configured to generate the mid-point resistance. When read_ref is ‘0’ and read_refb is ‘1’, the mid-point reference unit may be in the mid-point programming mode. During the mid-point programming mode, the mid-point resistance reference unit 1200 may be configured such that it is broken down to four 1 transistor/selector+1 memory cell (1T1R) units connected in parallel. Therefore, the four 1T1R units maybe be programmed separately with the control of the wordlines of the four selectors (w1_ref1, w1_ref2, w1_ref3 and w1_ref4).

FIG. 18 shows a timing diagram 1800 of the control signals of the mid-point reference unit 1700 according to various embodiments. The timing diagram 1800 shows the timing waveform of the control signals of the mid-point reference unit 1700 during programming. The timing diagram 1800 includes a horizontal axis 1802 indicating time in nanoseconds (ns) and a plurality of vertical axes 1804 indicating voltage in volts (V). The timing diagram 1800 includes the transient response of the clock signal (clk) 1880, the transient response of the rstb signal 1882, the transient response of the we_ref signal 1884, the transient response of the w1_ref4 1886, the transient response of the w1_ref3 1888, the transient response of the w1_ref2 1890 and the transient response of the w1_ref1 1892. The programming of the mid-point reference TEFRAM cells 1220 may occur during the power-on of the nonvolatile memory or during a calibration mode. It may be controlled by the write enable reference (we_ref) signal 1884. When the we_ref signal 1884 is high, four pulses, namely w1_ref1 1892, w1_ref2 1890, w1_ref3 1888 and w1_ref4 1886, may be generated sequentially for the four mid-point selectors and the write drivers. The programme scheme may be the same as that for normal TEFRAM cells 1220, i.e. by adopting the read-before-write scheme. Two of the memory cells 1220 may be programmed to high resistance state and the other two memory cells 1220 may be programmed to low resistance state by providing the corresponding input data signal during programming. The mid-point reference units may be programmed byte-by-byte by controlling the address signals.

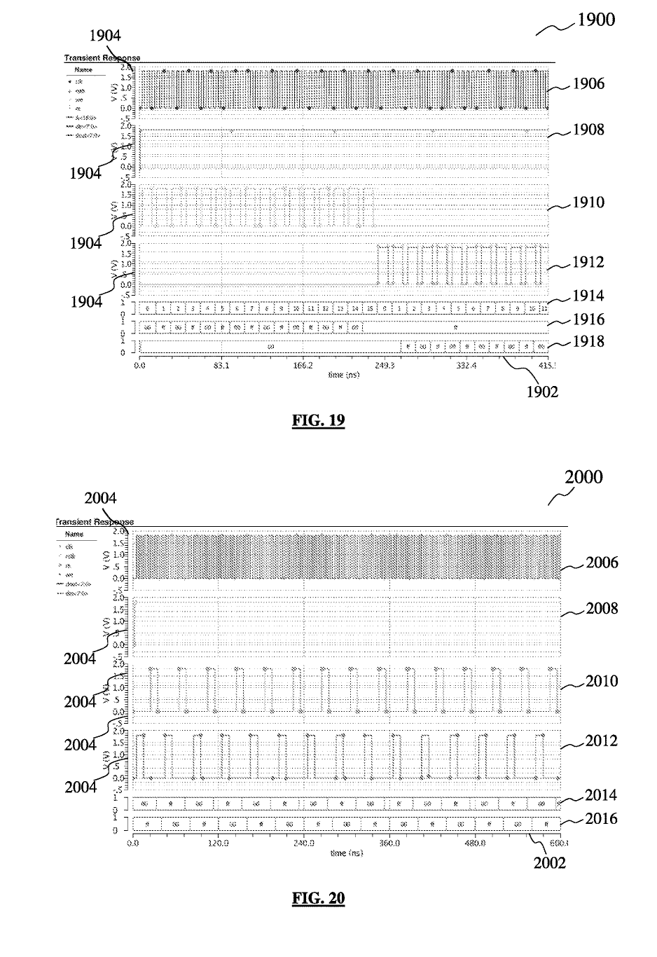

FIG. 19 shows a timing diagram 1900 showing the signal waveforms during operation of a TEFRAM in a burst-mode operation, according to various embodiments. The timing diagram 1900 includes a horizontal axis 1902 indicating time in nanoseconds (ns) and a plurality of vertical axes 1904 indicating voltage in volts (V). The timing diagram 1900 includes the transient response of the clock signal (clk) 1906, the transient response of the reset signal (rstb) 1908, the write enable signal (we) signal 1910, the read enable signal (re) 1912, the address (A) signal 1914, the input data signal (din) 1916 and the output data signal (dout) 1918. During the burst-mode operation, a series of write enable pulses may be generated to write the input data to a number of memory addresses. Subsequently, during the read phase, a series of read enable pulses may be generated to read the data stored in memory. By writing and reading the data in group (for example, a page), the write and read latency may be shortened, thereby resulting in faster memory access. During the write operation, the address signal 1914 may be swept from 0 to 15 to write to 16 memory cells and during read operation, the same cells may be read out sequentially.

FIG. 20 shows a timing diagram 2000 showing the signal waveforms during the normal mode operation of a TEFRAM according to various embodiments. The timing diagram 2000 includes a horizontal axis 2002 indicating time in nanoseconds (ns) and a plurality of vertical axes 2004 indicating voltage in volts (V). The timing diagram 2000 includes the transient response of the clock signal (clk) 2006, the transient response of the reset signal (rstb) 2008, the read enable signal (re) 2010, the write enable signal (we) 2012, the data output (dout) signal 2014 and the input data (din) signal 2016. During the normal-mode operation, the write and read pulses may occur randomly. When the write enable is high, input data are written to the memory based on the selected address. When the read enable is high, data may be loaded to the data output based on the address signals.

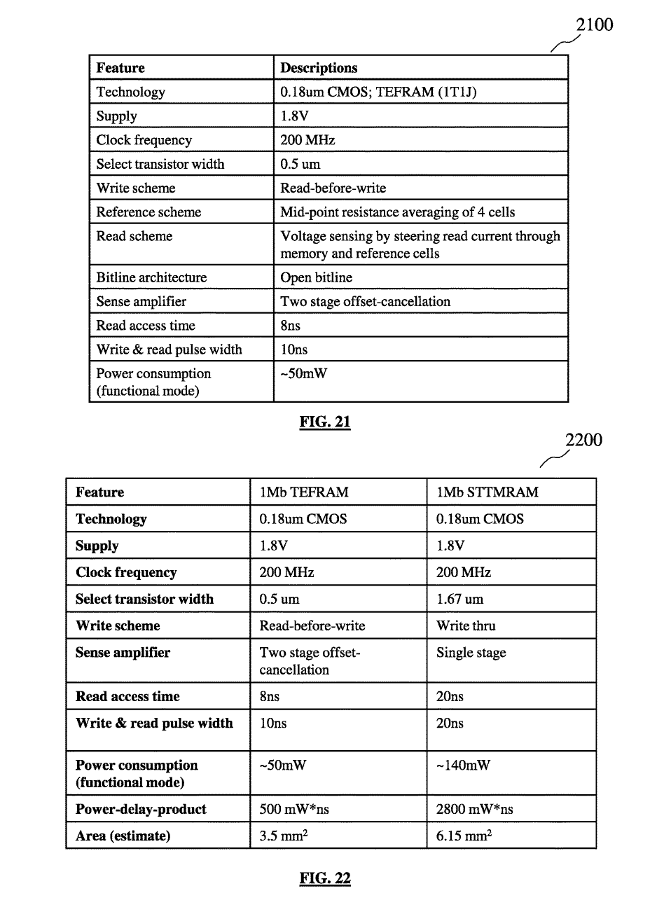

FIG. 21 shows a table 2100 summarizing the features of a memory device according to various embodiments.

FIG. 22 shows a table 2200 summarizing a list of differences between a memory device according to various embodiments, as compared to a prior art STTRAM.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced. It will be appreciated that common numerals, used in the relevant drawings, refer to components that serve a similar or the same purpose.

1. A memory device comprising:
a sense amplifier having a first side and a second side, wherein the second side opposes the first side;
a first array comprising a plurality of memory cells arranged at the first side;
a second array comprising a plurality of memory cells arranged at the second side;
a first row comprising a plurality of mid-point reference units arranged at the first side; and
a second row comprising a plurality of mid-point reference units arranged at the second side,
wherein each mid-point reference unit of the first row is configured to generate a first reference voltage, and wherein each mid-point reference unit of the second row is configured to generate a second reference voltage;
wherein the sense amplifier is configured to determine a resistance state of a memory cell of the first array based on the second reference voltage;
wherein the sense amplifier is configured to determine a resistance state of a memory cell of the second array based on the first reference voltage.

2. The memory device of claim 1, wherein the sense amplifier is configured to determine a resistance state of the memory cell of the first array based on the second reference voltage generated by a mid-point reference unit in a same column as the memory cell of the first array; and wherein the sense amplifier is configured to determine a resistance state of the memory cell of the second array based on the first reference voltage generated by a mid-point reference unit in a same column as the memory cell of the second array.

3. The memory device of claim 1, wherein each of the first array and the second array comprises a plurality of columns, wherein each column of the plurality of columns comprises a plurality of memory cells.

4. The memory device of claim 3, wherein a quantity of mid-point reference units in the second row is the same as a quantity of columns in the first array; and wherein a quantity of mid-point reference units in the first row is the same as a quantity of columns in the second array.

5. The memory device of claim 1, wherein the sense amplifier is configured to compare a voltage of the memory cell of the first array with the second reference voltage.

6. The memory device of claim 1, further comprising:
a write driver configured to toggle the resistance state of at least one of the memory cell of the first array or the memory cell of the second array between a high resistance state and a low resistance state.

7. The memory device of claim 6, wherein the sense amplifier is configured to determine the resistance state of the at least one of the memory cell of the first array or the memory cell of the second array before the write driver toggles the resistance state of the at least one of the memory cell of the first array or the memory cell of the second array.

8. The memory device of claim 1, wherein the sense amplifier comprises
a first amplifier stage;
a second amplifier stage; and
a plurality of capacitors connected between the first amplifier stage and the second amplifier stage.

9. The memory device of claim 8, wherein the plurality of capacitors are configured, in a first mode of operation, to charge to a voltage corresponding to an offset voltage induced between inputs of the sense amplifier, and further configured, in a second mode of operation, to discharge the plurality of capacitors to counter the offset voltage induced between inputs of the sense amplifier.

10. The memory device of claim 1, wherein each mid-point reference unit of each of the first row and the second row comprises four memory cells; and wherein in a programming mode, the four memory cells are connected in parallel.

11. The memory device of claim 10, wherein in the programming mode, a write driver is configured to program two memory cells to high resistance state and two memory cells to low resistance state.

12. The memory device of claim 1, wherein each mid-point reference unit of each of the first row and the second row comprises four memory cells; and wherein in a read mode, the four memory cells are arranged in two branches connected in parallel, wherein each branch of the two branches comprises a memory cell in high resistance state connected in series to a memory cell in low resistance state.

13. The memory device of claim 1, further comprising:
a controller electrically coupled to the sense amplifier, wherein the controller is configured to generate internal control signals.

14. The memory device of claim 13, wherein the controller is configured to sample rising edges of a clock signal and falling edges of the clock signal, and is further configured to align the internal control signals to the rising edges of the clock signal and the falling edges of the clock signal.

15. The memory device of claim 13, wherein the controller comprises a plurality of digital delay elements configured to align edges of the internal control signals to the rising edges of the clock signal and the falling edges of the clock signal.

16. The memory device of claim 13, wherein the controller is further configured to compare an input data to the resistance state of a memory cell, the input data being data that is to be written to the memory cell.

17. The memory device of claim 13, wherein the controller is further configured to generate the internal control signals to toggle the resistance state of the at least one of the memory cell of the first array or the memory cell of the second array if the resistance state of the at least one of the memory cell of the first array or the memory cell of the second array is not at least substantially matched to the input data.

18. The memory device of claim 1, wherein each memory cell of each of the first array and the second array comprises:
a reference magnetic layer structure having a fixed magnetization orientation; and
a synthetic antiferromagnetic layer structure comprising a free magnetic layer structure and a coupling magnetic layer structure antiferromagnetically coupled to each other, each of the free magnetic layer structure and the coupling magnetic layer structure having a magnetization orientation that is variable,
wherein the reference magnetic layer structure and the synthetic antiferromagnetic layer structure are arranged one over the other.

19. A method for operating a memory device, the method comprising:
providing a sense amplifier, the sense amplifier having a first side and a second side, wherein the second side opposes the first side;
providing a first array comprising a plurality of memory cells arranged at the first side;
providing a second array comprising a plurality of memory cells arranged at the second side;
providing a first row comprising a plurality of mid-point reference units arranged at the first side;
providing a second row comprising a plurality of mid-point reference units arranged at the second side; and
determining at least one of a resistance state of a memory cell of the second array based on a first reference voltage or a resistance state of a memory cell of the first array based on a second reference voltage;
wherein the first reference voltage is generated by a mid-point reference unit of the first row, and
wherein the second reference voltage is generated by a mid-point reference unit of the second row.

20. The method of claim 19, further comprising:
receiving an input data;
comparing the input data to the determined resistance state;
toggling the determined resistance state if the determined resistance state is not at least substantially matched to the input data.
